(19) United States
(12) Patent Application Publication
(10) Pub. No.: US 2007/0030033 A1
(43) Pub. Date: Feb. 8, 2007

(54) Fast peak detector circuit

(76) Inventor: Jack Gershfeld, Fullerton, CA (US)

Correspondence Address: VLADIMIR KHITERER;KHITERER LAW OFFICE, 2109 W. COAST HWY., SUITE 200, NEWPORT BEACH, CA, 92663, US

(21) Appl. No.: 11/196,196

(22) Filed: Aug. 4, 2005

(51) Int. Cl. H03K 5/153

(52) U.S. Cl. 327/58

(57) ABSTRACT

A peak detector circuit for video signals is disclosed. The peak detector circuit comprises a buffer operational amplifier, a strap diode and feedback resistor in order to bootstrap an operational amplifier used in the circuit and to isolate and provide feedback for the circuit An alternative embodiment of this invention utilizes a transistor instead of a strap diode to provide faster charging for a hold capacitor used in the circuit through current gain action of the transistor. The peak detector circuit of this invention permits tracing the input voltage while the operational amplifier remains in the active region, where it is the fastest, without going into saturation during negative cycles of the signal.

### BACKGROUND OF THE INVENTION

This invention pertains to a fast peak detector circuit for use in video equipment. Peak detectors are well known to the persons knowledgeable in the pertinent arts as important components in electronic design that can be used to measure amplitude of a signal. Peak detectors are typically used in measuring signal strength or as part of an automatic gain control circuitry. When peak detectors are used in video equipment, speed with which peak detectors react to the input signal is very important because video signals are very fast and the peak portion of the signal may contain very little energy, thus making it difficult to detect and trace.

### DESCRIPTION OF PRIOR ART

Disadvantages of the peak detectors of the prior art, when used with video signals, will be better understood with reference to FIG. 1 and FIG. 2. FIG. 1 shows a typical peak detector comprising a rectifying element (indicated by “Peak Detect Diode”) and peak hold capacitor (indicated by “Hold Capacitor”). The graph in the right portion of FIG. 1 shows the input and output voltage during the positive and negative cycles of the input voltage. Said graph shows that the output peak voltage is lower than the input peak voltage by approximately 0.7 Volts. This represents the voltage drop across the diode (i.e. the Peak Detect Diode).

FIG. 2 shows a more advanced version of a peak detector that eliminates the voltage drop across the diode discussed above. Specifically, an operational amplifier (indicated by “Op-Amp”) is used with Peak Detect Diode in the feedback loop of the operational amplifier. As the graph in the right portion of FIG. 2 shows, this eliminates the voltage drop across Peak Detect Diode. The circuit shown in FIG. 2 works very well for slow signals. However, it does not work well for fast signals, such as video signals.

The limitation comes from the operational amplifier going into saturation during negative cycles of the signal. Once in the saturation mode, it takes a very long time for the operational amplifier to recover and return to the active region and trace the incoming signal. Typically, an operational amplifier is powered from a +/− power supply. In video applications, +/−5V power supply is often used. If, for example, the detected voltage was 1 Volt and the input voltage then drops bellow 1 Volt, the output of the operational amplifier will be driven to −5 Volt rail until the input voltage goes above 1 Volt. To trace the input voltage, the operational amplifier must go back up to 1 Volt. However, it will take significant amount of time for the operational amplifier to recover from −5 Volts back to 1 Volt.

What is needed, therefore, is a peak detector that permits tracing the input voltage while the operational amplifier remains in the active region, where it is the fastest, without going into saturation during negative cycles of the signal.

### SUMMARY OF THE INVENTION

The fast peak detector circuit of the present invention satisfies the above need. Specifically, the present invention utilizes three additional components to bootstrap the operational amplifier and to isolate and provide feedback for the circuit, namely, a buffer operational amplifier, a strap diode and feedback resistor. An alternative embodiment of this invention utilizes a transistor instead of a strap diode to provide faster charging for Hold Capacitor through current gain action of the transistor.

### BRIEF DESCRIPTION OF THE DRAWINGS FIGURES

FIG. 3 shows a schematic representation of the fast peak detector according to the first embodiment of this invention, as well as the graph that illustrates the operation of said embodiment.

FIG. 4 shows a schematic representation of the fast peak detector according to the second embodiment of this invention, as well as the graph that illustrates the operation of said embodiment.

### DETAILED DESCRIPTION OF THE PREFERRED EMBODIMENTS

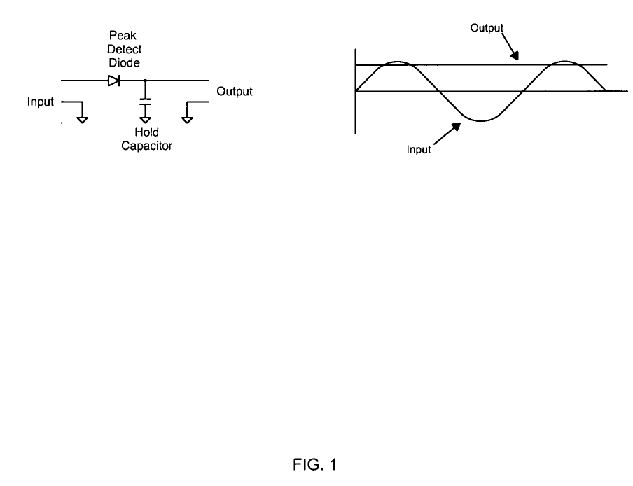

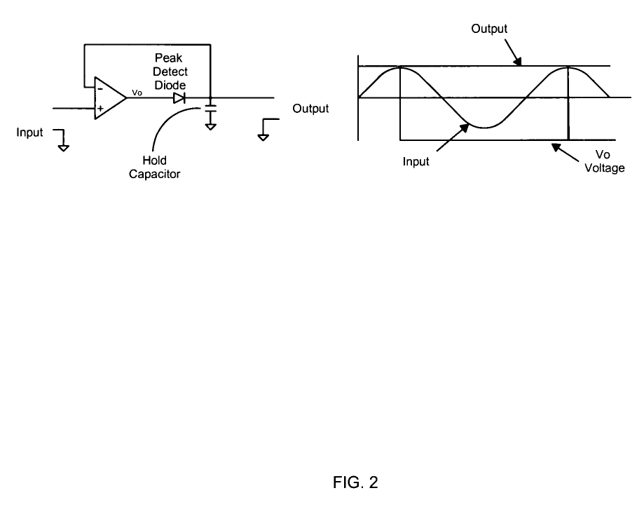

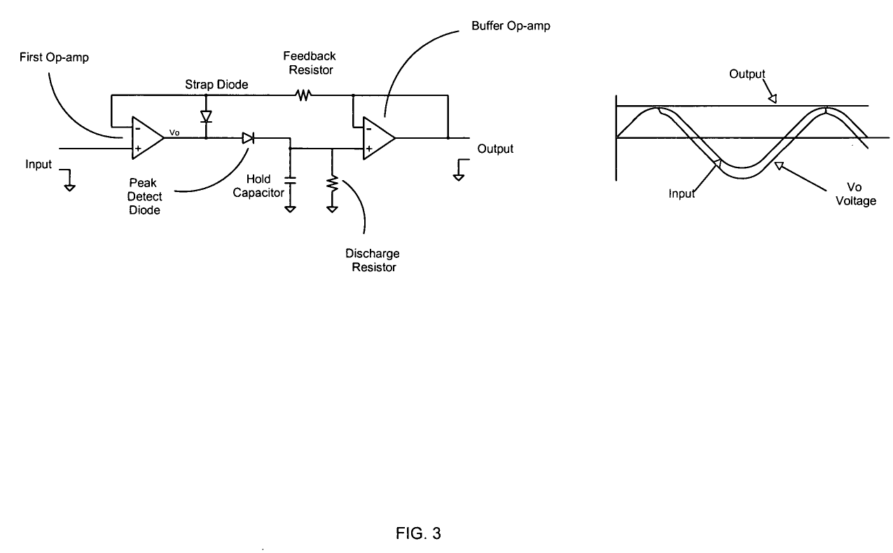

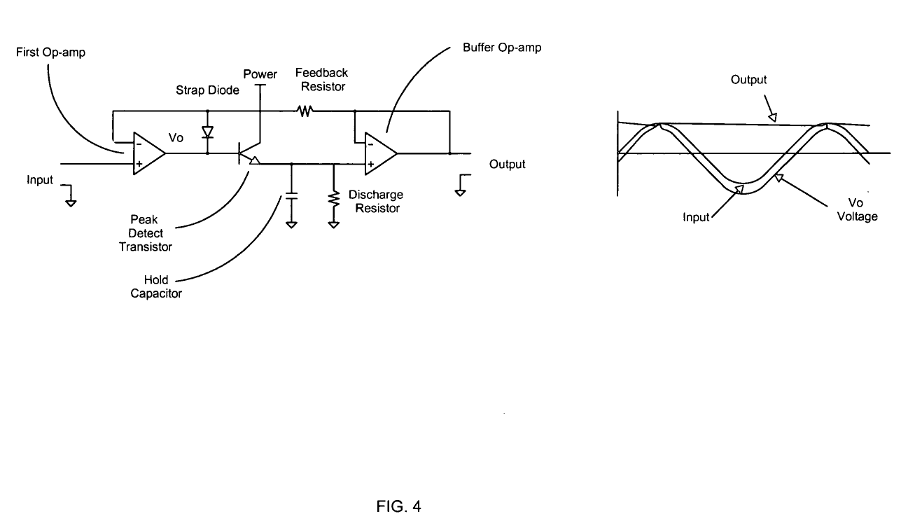

This invention will be better understood with the reference to the drawing figures FIG. 3 and FIG. 4. The same references pertain to the same elements in all drawing figures.

Viewing FIG. 3, there is shown a schematic representation of the fast peak detector according to the first embodiment of this invention, as well as the graph that illustrates the operation of said embodiment. The referenced “First Op-amp” indicates a first operational amplifier. First Op-amp has first and second inputs and an output, the first input is coupled to an input terminal indicated by the reference “Input”. An input voltage is applied to Input. The referenced “Vo” indicates voltage at the output of First Op-amp.

The reference “Strap Diode” indicates a strap diode. Strap Diode has an input and an output. The reference “Peak Detect Diode” indicates a peak detect diode. Peak Detect Diode has an input and an output. Peak Detect Diode is reverse biased.

The reference “Feedback Resistor” indicates a feedback resistor. Feedback Resistor has a first and a second terminal. The reference “Hold Capacitor” indicates a hold capacitor. Hold Capacitor has an input and an output, the output of Hold Capacitor is coupled to a ground terminal.

The reference “Buffer Op-amp” indicates a buffer operational amplifier. Buffer Op-amp has first and second inputs and an output. The reference “Discharge Resistor” indicates a discharge resistor. Discharge Resistor has a first and second terminals. The second terminal of Discharge Resistor is coupled to the ground terminal.

The output of First Op-amp is coupled to the output of Strap Diode and also to the input of Peak Detect Diode. The first input of Buffer Op-amp is coupled to the second terminal of Feedback Resistor, to the output of Buffer Op-amp and to an output terminal indicated by the reference “Output”. The second input of Buffer Op-amp is coupled to the output of Peak Detect Diode, to the input of Hold Capacitor and also to the first terminal of Discharge Resistor.

The graph in the right portion of FIG. 3 shows the input and output voltage during the positive and negative cycles of the input voltage.

First Op-amp must be fast enough to be able to pass the fast video signal coming in. First Op-amp must have a bandwidth of greater than 100 Mhz.

Still viewing FIG. 3, as shown in the graph, the input voltage can be positive or negative. Once Hold Capacitor is charged during the positive cycle of the input voltage, the voltage on Hold Capacitor represents the peak voltage of the signal. However, as the signal decreases in amplitude, Hold Capacitor needs to be discharged to assume the new voltage level. Discharge Resistor is used to discharge the capacitor when signal amplitude changes.

As input signal decreases after the peak value, the positive input of First Op-amp drops bellow the negative input of First Op-amp. This causes Vo to go negative, which in turn turns Strap Diode on and straps the output voltage to be within the voltage drop of Strap Diode from the input voltage. As such, the operation of Strap Diode and Buffer Op-amp prevents First Op-amp from going into saturation and allows First Op-amp to always operate in the active region, which allows peak detection of fast signals.

It has been determined by way of experiments that the peak detector circuit of this invention performs best when the elements of the circuit have the values described below.

Specifically, First Op-amp should have a bandwidth greater than about 100 Megahertz. Strap Diode should have reverse recovery time ranging from about 1 nanosecond to about 50 nanoseconds, and particularly about 5 nanoseconds. The persons knowledgeable in the pertinent arts will recognize that reverse recovery time is the time it takes for a diode to switch from being reverse biased to being forward biased. Peak Detect Diode should have turn on time ranging from about 1 nanosecond to about 100 nanoseconds, particularly about 4 nanoseconds. The persons knowledgeable in the pertinent arts will recognize that turn on time is the time it takes for a diode to start conducting current.

Hold Capacitor should have capacitance ranging from about 10 pf to about 1000 pf, and particularly about 100 pf. Buffer Op-amp should have impedance on the first input greater than about 10M Ohms.

Viewing now FIG. 4, there is shown a schematic representation of the fast peak detector according to the second embodiment of this invention, as well as the graph that illustrates the operation of said embodiment. The second embodiment of this invention differs from the first embodiment describe in reference to FIG. 3 in that a peak detect transistor indicated by the reference “Peak Detect Transistor” is used in place of Peak Detect Diode. Peak Detect Transistor has a collector, a base and an emitter, the collector is coupled to a power source indicated by the reference “Power”.

The base is coupled to the output of First Op-amp and to the output of Strap Diode. The emitter is coupled to the second input of Buffer Op-amp, to the input of Hold Capacitor and to the first terminal of Discharge Resistor.

Peak Detect Transistor draws current from Power and provides current gain for faster charging of Hold Capacitor. In all other respects, the operation of the peak detect circuit according to the second embodiment is identical to that of the first embodiment.

While the present invention has been described and defined by references to the preferred embodiments of the invention, such references do not imply a limitation on the invention, and no such limitation is to be inferred. The invention is capable of considerable modification, alteration, and equivalents in form and function, as will occur to those ordinarily skilled and knowledgeable in the pertinent arts. The depicted and described preferred embodiments of the invention are exemplary only, and are not exhaustive of the scope of the invention. Consequently, the invention is intended to be limited only by the spirit and scope of the appended claims, giving full cognizance to equivalents in all respects.

What is claimed is:

1) A peak detector circuit, comprising:
a first operational amplifier having first and second inputs and an output, the first input being coupled to an input terminal to which an input voltage is applied;
a strap diode having an input and an output;
a peak detect diode having an input and an output, the peak detect diode being reverse biased;
a feedback resistor having a first and second terminals;
a hold capacitor having an input and an output, the output of the hold capacitor being coupled to a ground terminal;
a buffer operational amplifier having first and second inputs and an output;
a discharge resistor having a first and second terminals, the second terminal of the discharge resistor being coupled to the ground terminal;
wherein the second input of the first operational amplifier being coupled to the first terminal of the feedback resistor and to the input of the strap diode;
wherein the output of the first operational amplifier being coupled to the output of the strap diode and to the input of the peak detect diode;
wherein the first input of the buffer operational amplifier being coupled to the second terminal of the feedback resistor, to the output of the buffer operational amplifier and to an output terminal;
wherein the second input of the buffer operational amplifier being coupled to the output of the peak detect diode, to the input of the hold capacitor and to the first terminal of the discharge resistor;

2) A peak detector circuit as in claim 1, wherein:
the first operational amplifier having a bandwidth greater than about 100 Megahertz;
the strap diode having a reverse recovery time ranging from about 1 nanosecond to about 50 nanoseconds;
the peak detect diode having a turn on time ranging from about 1 nanosecond to about 100 nanoseconds;
the feedback resistor having resistance ranging from about 1K Ohms to about 100K Ohms;
the hold capacitor having capacitance ranging from about 10 pf to about 1000 pf;
buffer operating amplifier having impedance on the first input greater than about 10M Ohms.

3) A peak detector circuit as in claim 2, wherein:
the strap diode having the reverse recovery time of about 5 nanoseconds;
the peak detect diode having the turn on time of about 4 nanoseconds;
the hold capacitor having capacitance of about 100 pf.

4) A peak detector circuit, comprising:
a first operational amplifier having first and second inputs and an output, the first input being coupled to an input terminal to which an input voltage is applied;
a strap diode having an input and an output;
a peak detect transistor having a collector, a base and an emitter, the collector being coupled to a power source;
a feedback resistor having a first and second terminals;
a hold capacitor having an input and an output, the output of the hold capacitor being coupled to the ground terminal;
a buffer operational amplifier having first and second inputs and an output;
a discharge resistor having a first and second terminals, the second terminal of the discharge resistor being coupled to the ground terminal;
wherein the second input of the first operational amplifier being coupled to the first terminal of the feedback resistor and to the input of the strap diode;
wherein the output of the first operational amplifier being coupled to the output of the strap diode and to the base;
wherein the first input of the buffer operational amplifier being coupled to the second terminal of the feedback resistor, to the output of the buffer operational amplifier and to an output terminal;
wherein the second input of the buffer operational amplifier being coupled to the emitter, to the input of the hold capacitor and to the first terminal of the discharge resistor;

5) A peak detector circuit as in claim 4, wherein:
the first operational amplifier having a bandwidth greater than about 100 Megahertz;
the strap diode having a reverse recovery time ranging from about 1 nanosecond to about 50 nanoseconds;
the feedback resistor having resistance ranging from about 1 K Ohms to about 100K Ohms;
the hold capacitor having capacitance ranging from about 10 pf to about 1000 pf;
buffer operating amplifier having impedance on the first input greater than about 10M Ohms.

6) A peak detector circuit as in claim 5, wherein:
the strap diode having the reverse recovery time of about 5 nanoseconds;
the peak detect diode having the turn on time of about 4 nanoseconds;
the hold capacitor having capacitance of about 100 pf.
